(19) United States
(12) Patent Application Publication
(10) Pub. No.: US 2016/0147326 A1
(43) Pub. Date: May 26, 2016

(54) SENSING SCREEN AND METHOD FOR MANUFACTURING THE SAME

(71) Applicant: HON HAI PRECISION INDUSTRY CO., LTD., New Taipei (TW)

(72) Inventor: KUO-HSIANG OU YANG, New Taipei (TW)

(21) Appl. No.: 14/585,560

(22) Filed: Dec. 30, 2014

(30) Foreign Application Priority Data
Nov. 25, 2014 (TW) 103140721

(51) Int. Cl. G06F 3/041; H05K 3/36; H05K 3/14

(52) U.S. Cl. CPC G06F 3/041; H05K 3/146; H05K 3/365; G06F 2203/04102; G06F 2203/04103

(57) ABSTRACT

The sensing screen includes a display module having a top surface, a glass panel, and a conductive coating. The glass panel is configured to cover the top surface of the display module and has an upper surface and a bottom surface. The conductive coating is configured to coat the bottom surface of the glass panel and is positioned between the bottom surface of the glass panel and the top surface of the display module. The conductive coating is configured to sense if an electronic stylus is proximate the upper surface of the glass panel. A manufacturing method of the sensing screen is also provided.

### FIELD

The subject matter herein generally relates to sensing screens and a method for manufacturing the same.

### BACKGROUND

Nowadays, electronic devices, such as tablet computers and smart phones, include sensing screens for touch operations. Users can operate the electronic devices with the sensing screens not only by fingers but also by electronic stylus. Usually, each sensing screen includes a display module and a flexible circuit board. The flexible circuit board completely covers a bottom surface of the display module.

### BRIEF DESCRIPTION OF THE DRAWINGS

Many aspects of the disclosure can be better understood with reference to the following drawings. The components in the drawings are not necessarily drawn to scale, the emphasis instead being placed upon clearly illustrating the principles of the disclosure. Moreover, in the drawings, like reference numerals designate corresponding parts throughout the views.

FIG. 1 is an exploded view of an embodiment of a sensing screen.

FIG. 2 is an assembled view of the sensing screen of FIG. 1.

FIG. 3 is a partial, cross-sectional, diagrammatic view of FIG. 1.

FIG. 4 is a flow chart of a method of the sensing screen in accordance with an embodiment.

### DETAILED DESCRIPTION

It will be appreciated that for simplicity and clarity of illustration, where appropriate, reference numerals have been repeated among the different figures to indicate corresponding or analogous elements. In addition, numerous specific details are set forth in order to provide a thorough understanding of the embodiments described herein. However, it will be understood by those of ordinary skill in the art that the embodiments described herein can be practiced without these specific details. In other instances, methods, procedures and components have not been described in detail so as not to obscure the related relevant feature being described. The drawings are not necessarily to scale and the proportions of certain parts may be exaggerated to better illustrate details and features. The description is not to be considered as limiting the scope of the embodiments described herein. It should be noded that references to “an” or “one” embodiment in this disclosure are not necessarily to the same embodiment, and such references can mean “at least one.”

Several definitions that apply throughout this disclosure will now be presented.

The term “coupled” is defined as connected, whether directly or indirectly through intervening components, and is not necessarily limited to physical connections. The connection can be such that the objects are permanently connected or releasably connected. The term “comprising” means “including, but not necessarily limited to”; it specifically indicates open-terminal inclusion or membership in a so-described combination, group, series and the like.

The present disclosure is described in relation to a sensing screen. The sensing screen includes a display module having a top surface, a glass panel, and a conductive coating. The glass panel is configured to cover the top surface of the display module and has an upper surface and a bottom surface. The conductive coating is configured to coat the bottom surface of the glass panel and is positioned between the bottom surface of the glass panel and the top surface of the display module. The conductive coating is configured to sense if an electronic stylus is proximate the upper surface of the glass panel. The present further discloses a manufacturing method of the sensing screen.

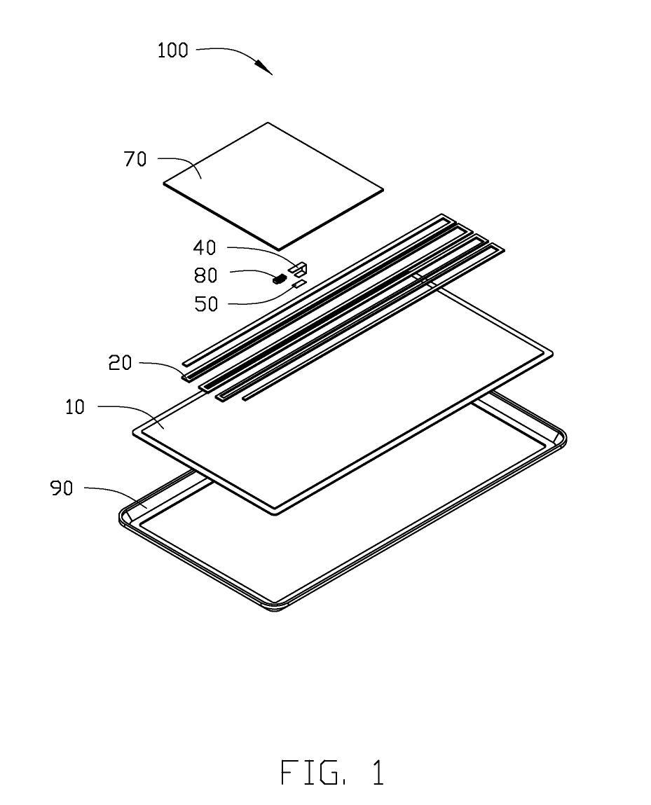

FIG. 1 illustrates an embodiment of a sensing screen 100 configured to be used in a variety of electronic devices (not shown), such as smart phones and tablet computers. The sensing screen 100 is configured to sense electronic styluses (not shown); thereby the electronic devices are able to be operated by the electronic styluses.

The sensing screen 100 includes a glass panel 10, a display module 30, a flexible circuit board 40, a motherboard 70, a connector 80, and a frame 90.

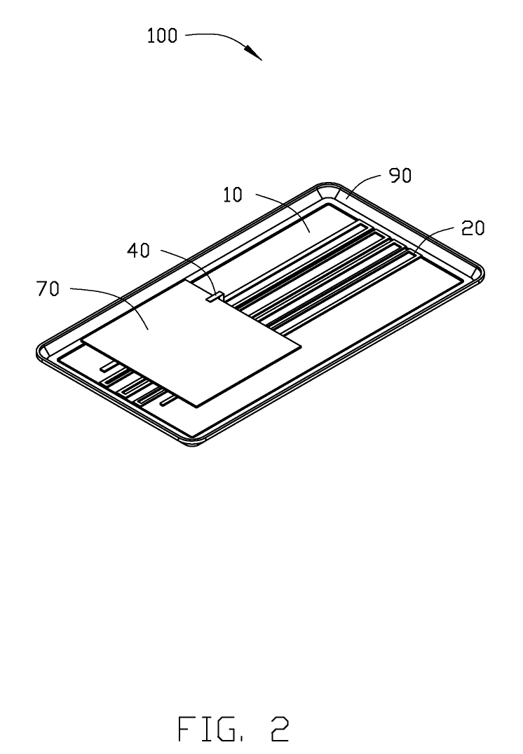

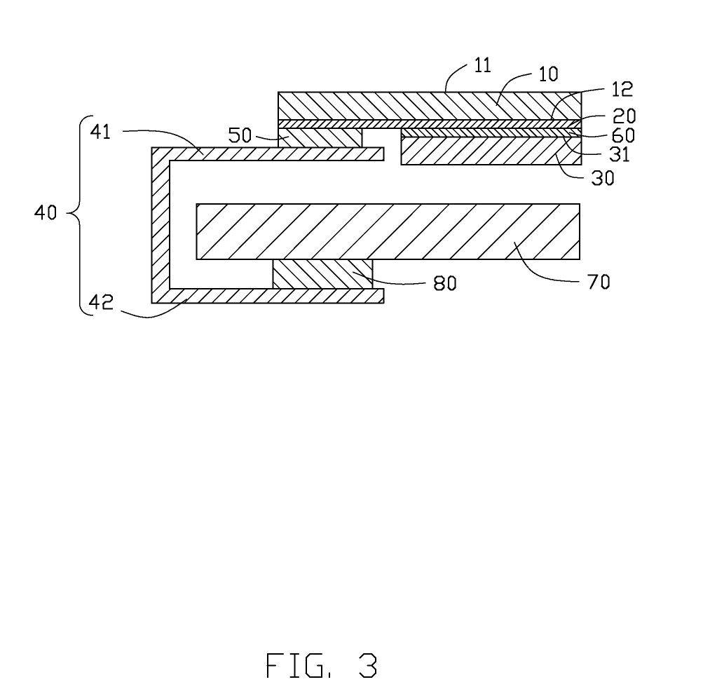

FIGS. 2-3 illustrate that, the glass panel 10 has an upper surface 11 and a bottom surface 12. The glass panel 10 is configured to cover a top surface 31 of the display module 30. A conductive coating 20 is configured to coat the bottom surface 12 of the glass panel 10 and is located between the bottom surface 12 of the glass panel 10 and the top surface 31 of the display module 30. The conductive coating 20 coated on the glass panel 10 is a conducting circuit. The conductive coating 20 is configured to sense if the electronic stylus is proximate the upper surface 11 of the glass panel 10. When the glass panel 10 is operated by each electronic stylus, the conductive coating 20 is configured to sense the electronic stylus and generate an operation signal.

In at least one embodiment, the conductive coating is an indium tin oxide (ITO) coating. The conductive coating 20 is coated to the bottom surface 12 of the glass panel 10 by a physical vapor deposition technology or a chemical vapor deposition.

In another embodiment, a thickness of the glass panel 10 is about 0.7 millimeter. The conductive coating 20 is coated to the glass panel 10 by a nano coating technology. Thereby, a thickness of the conductive coating 20 is approximately equal to zero.

In at least one embodiment, an unnecessary area of the conductive coating 20 is removed by a laser etching technology to form the conductive circuit.

The motherboard 70 and the flexible circuit board 40 are located under the conductive coating 20. The conductive coating 20 is coupled to the motherboard 70 via the flexible circuit board 40. The operation signal is configured to be transmitted from the conductive coating 20 to the motherboard 70 via the flexible circuit board 40. The flexible circuit board 40 is substantially U-shaped. A first side 41 of the flexible circuit board 40 is coupled to the conductive coating 20, and a second side 42 of the flexible circuit board 40 is coupled to the motherboard 70 via the connector 80. The second side 42 is opposite to the first side 41. The motherboard 70 is located between the first side 41 and the second side 42. In at least one embodiment, the connector 80 is a board to board connector. The first side of the flexible circuit board 40 and the display module 30 are not overlapping. In at least one embodiment, the first side 41 of the flexible circuit board 40 and the display module 30 are substantially located on a same plane.

FIGS. 2-3 illustrate an assembled view of the sensing screen 100. The frame 90 is attached to the glass panel 10. The conductive coating 20 is coated to the bottom of the glass panel 10 and forms the conductive circuit. The conductive coating 20 is coupled to the first side 41 of the flexible circuit board 40 by a first adhesive 50, and is coupled to the display module 30 by a second adhesive 60. The motherboard 70 is coupled to the second side of the flexible circuit board 70.

In at least one embodiment, the first adhesive 50 is anisotropic conductive adhesive (ACA), and the second adhesive 60 is optically conductive adhesive (OCA).

The flexible circuit 40 in the sensing screen 100 is used for transmitting the operation signal. Thereby, the flexible circuit board 40 in the sensing screen 100 has no need to completely cover a bottom surface (not label) of the display module 30 for sensing the electronic styluses.

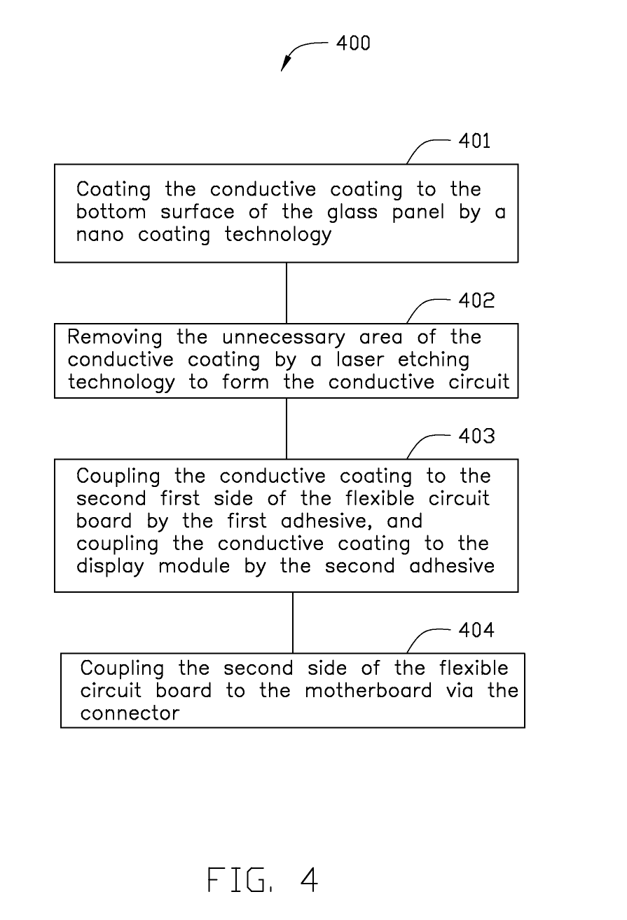

Referring to FIG. 4, a flowchart is presented in accordance with an example embodiment. The example method 400 is provided by way of example, as there are a variety of ways to carry out the method. The method described below can be carried out using the configurations illustrated in FIGS. 1-3, for example, and various elements of these figures are referenced in explaining example method 400. Each block shown in FIG. 4 represents one or more processes, methods or subroutines, carried out in the example method 400. Furthermore, the illustrated order of blocks is illustrative only and the order of the blocks can change according to the present disclosure. Additional blocks can be added or fewer blocks may be utilized, without departing from this disclosure. The example method 400 can begin at block 401.

At block 401: the conductive coating 20 is coated on the bottom surface 12 of the glass panel 10 by a nano coating technology. In at least one embodiment, the conductive coating 20 is coated on the bottom surface 12 of the glass panel 10 by a physical vapor deposition technology or chemical vapor deposition technology.

At block 402: the unnecessary area of the conductive coating 20 is removed by a laser etching technology to form the conductive circuit.

At block 403: the conductive coating 20 is coupled to the first side 41 of the flexible circuit board 40 by the first adhesive and is coupled to the display module 30 by the second adhesive.

At block 404: the second side 42 of the flexible circuit board 40 is coupled to the motherboard 70 via the connector 80.

The embodiments shown and described above are only examples. Even though numerous characteristics and advantages of the present technology have been set forth in the foregoing description, together with details of the structure and function of the present disclosure, the disclosure is illustrative only, and changes may be made in the detail, including in matters of shape, size and arrangement of the parts within the principles of the present disclosure up to, and including, the full extent established by the broad general meaning of the terms used in the claims.

What is claimed is:

1. A sensing screen comprising:
a display module having a top surface;
a glass panel configured to cover the top surface of the display module, the glass panel having an upper surface and a bottom surface; and
a conductive coating located between the bottom surface of the glass panel and the top surface of the display module;
wherein the conductive coating is configured to sense if an electronic stylus is proximate the upper surface of the glass panel.

2. The sensing screen of claim 1, wherein the conductive coating coated on the bottom surface of the glass panel is formed a conducting circuit.

3. The sensing screen of claim 1, wherein the conductive coating is an indium tin oxide coating.

4. The sensing screen of claim 1, further comprising a motherboard and a flexible circuit board, wherein the motherboard and the flexible circuit board are located under the conductive coating.

5. The sensing screen of claim 4, wherein the flexible circuit board and the display module are nonoverlapping.

6. The sensing screen of claim 4, wherein the conductive coating is coupled to the motherboard via the flexible circuit board.

7. The sensing screen of claim 6, wherein the flexible circuit board is substantially U-shaped, a first side of the flexible circuit board is coupled to the conductive coating, and a second opposite side of the flexible circuit board is coupled to the motherboard.

8. The sensing screen of claim 7, wherein the motherboard is located between the first side and the second side.

9. The sensing screen of claim 7, further comprising a connector, wherein the second side of the flexible circuit board is coupled to the motherboard via the connector.

10. The sensing screen of claim 7, wherein the first side of the flexible circuit board and the display module are substantially located on a same plane.

11. The sensing screen of claim 1, wherein the conductive coating is coated to the glass panel by a nano coating technology.

12. A manufacturing method of a sensing screen, comprising:
coating a conductive coating on a bottom surface of a glass panel;
removing an unnecessary area of the conductive coating to form a conductive circuit; and
coupling the conductive coating to a motherboard via a flexible circuit board, and coupling the conductive coating to a display module.

13. The manufacturing method of a sensing screen of claim 12, further comprising coating the conductive coating on the glass panel by a nano coating technology.

14. The manufacturing method of a sensing screen of claim 13, further comprising coating the conductive coating on the glass panel by a physical vapor deposition technology.

15. The manufacturing method of a sensing screen of claim 13, further comprising coating the conductive coating on the glass panel by a chemical vapor deposition technology.

16. The manufacturing method of a sensing screen of claim 12, wherein removing an unnecessary area of the conductive coating by a laser etching technology.

17. The manufacturing method of a sensing screen of claim 12, wherein coupling the conductive coating to the flexible circuit board by an adhesive.

18. The manufacturing method of a sensing screen of claim 12, wherein coupling the conductive coating to the display module by an adhesive.
